(19) United States
(12) Patent Application Publication
(10) Pub. No.: US 2002/0034585 A1
(43) Pub. Date: Mar. 21, 2002

(54) Silicon film forming process

(75) Inventors: Yasuo Matsuki, Chuo-ku (JP); Yasuaki Yokoyama, Chuo-ku (JP); Yasumasa Takeuchi, Chuo-ku (JP); Masahiro Furusawa, Suwa-shi (JP); Ichio Yudasaka, Chino-shi (JP); Satoru Miyashita, Suwa-shi (JP); Tatsuya Shimoda, Suwa-gun (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: JSR CORPORATION, Chuo-ku (JP)

(21) Appl. No.: 09/948,572

(22) Filed: Sep. 10, 2001

(30) Foreign Application Priority Data
Sep. 11, 2000 (JP) 2000-275233

(51) Int. Cl. B05D 3/04; B05D 3/02; C23C 16/00

(52) U.S. Cl. 427/228; 427/376.2; 427/377; 427/255.27

(57) ABSTRACT

A process capable of forming a silicon film on a substrate efficiently, for example, at a high yield and a high forming rate with simple operation and device unlike CVD and plasma CVD.

A process for forming a silicon film on a substrate by thermally decomposing at least one silicon compound selected from the group consisting of cyclopentasilane and silylcyclopentasilane in the presence of an inert organic medium vapor under atmospheric pressure.

### FIELD OF THE INVENTION

The present invention relates to a process for forming a silicon film on a substrate. More specifically, it relates to a process for forming a silicon film on a substrate with simple operation or equipment efficiently.

### DESCRIPTION OF THE PRIOR ART

Conventional processes for forming an amorphous silicon film or polysilicon film used in the production of a solar cell include thermal CVD (Chemical Vapor Deposition) and plasma CVD, both making use of monosilane gas or disilane gas, and photo CVD. Generally speaking, thermal CVD (refer to J. Vac. Sci. Technology, vol. 14, pp. 1082, 1977) is widely used to form a polysilicon film and plasma CVD (refer to Solid State Com., vol. 17, pp. 1193, 1975) is widely used to form an amorphous silicon film.

However, the formation of a silicon film by these CVD methods involves the following problems.

(1) Since a vapor phase reaction is used, silicon particles are generated in the vapor phase with the result of low production yield due to the pollution of equipment and the formation of foreign matter.

(2) Since the raw materials are gaseous, it is difficult to obtain a film which is uniform in thickness on a substrate having an uneven surface.

(3) Since the film forming rate is low, productivity is low.

(4) A complicated and expensive high-frequency generator and vacuum device are required for plasma CVD. Therefore, further improvement has been awaited.

Since gaseous silicon hydride having high toxicity and reactivity is used as a raw material, it is difficult to handle and a sealed vacuum device is necessary. As this type of device is generally bulky and is not only expensive but also a vacuum system and a plasma system consume a large amount of energy, they boost product cost.

### SUMMARY OF THE INVENTION

It is an object of the present invention to provide a process for forming a silicon film on a substrate.

It is another object of the present invention to provide a process for forming a silicon film, which is capable of forming a silicon film on a substrate efficiently, for example, at a high yield and a high forming rate with simple operation and device unlike CVD and plasma CVD.

It is still another object of the present invention to provide a process for forming a silicon film using cyclopentasilane or silylcyclopentasilane which is a stable compound unlike gaseous silicon hydride which has high toxicity and reactivity.

Other objects and advantages of the present invention will become apparent from the following description.

According to the present invention, firstly, the above objects and advantages of the present invention are attained by a process for forming a silicon film on a substrate, comprising thermally decomposing at least one silicon compound selected from the group consisting of cyclopentasilane and silylcyclopentasilane in the presence of an inert organic medium vapor.

### BRIEF DESCRIPTION OF THE ACCOMPANYING DRAWINGS

FIG. 1 is a schematic diagram of a device used in Example 1 for carrying out the process of the present invention; and

FIG. 2 is a Raman spectral diagram of a silicon film obtained in Example 1.

### DETAILED DESCRIPTION OF THE PREFERRED EMBODIMENT

The silicon compound used in the present invention is either one of cyclopentasilane and silylcyclopentasilane represented by the following formulas (1) and (2).

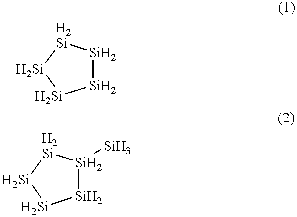

These silicon compounds can be produced through decaphenylcyclopentasilane and dodecaphenylcyclohexasilane which are produced from diphenyldichlorosilane as will be described in Synthesis Example 1.

In the present invention, these silicon compounds may be used alone or as a mixture thereof.

In the present invention, the silicon compound is thermally decomposed in the presence of an inert organic medium vapor. The inert organic medium is preferably a hydrocarbon or ether. A hydrocarbon is particuraly preferable. Examples of the hydrocarbon include aromatic hydrocarbons such as benzene, toluene and xylene, aliphatic hydrocarbons such as hexane, heptane and decane, and alicyclic hydrocarbons such as cyclopentane, cyclohexane and decalin. Examples of the ether include linear ethers such as diisopropyl ether and isopropylbutyl ether, and cyclic ethers such as tetrahydropyran, tetrahydrofuran and dioxane. These inert organic media may be used alone or in combination of two or more.

In the present invention, thermal decomposition may be carried out under atmospheric pressure, reduced pressure or increased pressure. It is preferably carried out under atmospheric pressure. Thermal decomposition is carried out at a temperature of preferably 200 to 600° C., more preferably 300 to 500° C. The silicon compound is thermally decomposed and silicon formed by thermal decomposition is accumulated on the substrate to give a silicon film.

The process of the present invention can be carried out as follows.

The process for forming a silicon film on a substrate comprises the steps of:

(1) introducing an inert gas into a mixture of at least silicon compound selected from the group consisting of cyclopentasilane and silylcyclopentasilane and an inert organic medium to form a gas mixture containing the above silicon compound and inert organic medium vapor on the inert gas carrier; and

(2) heating the gas mixture under atmospheric pressure to thermally decompose the silicon compound contained therein to accumulate silicon on the substrate.

In the above step (1), the mixture of the silicon compound and the inert organic medium is preferably in the form of a solution. The amount of the silicon compound is preferably adjusted to 0.01 to 50 wt %.

By introducing the inert gas into the mixture, a gas mixture containing the silicon compound and the inert organic medium vapor is easily formed. During the introduction of the inert gas, excessive heating is not preferred. The temperature of the mixture during the introduction of the inert gas is preferably kept at 10 to 50° C. During the introduction of the inert gas, a silicon compound and/or an inert organic medium may be added to the mixture as required.

The gas mixture obtained in the step (1) is introduced to carry out the step (2) in which the silicon compound is thermally decomposed under atmospheric pressure. The heating temperature is preferably 200 to 600° C. as described above. Silicon formed by the decomposition of the silicon compound is accumulated on the substrate to form a silicon film. To carry out the step (2), the gas mixture may be introduced continuously or intermittently. The introduction time may be suitably changed according to the content of the silicon compound in the gas mixture, the area of the substrate and the thickness of the silicon film to be formed. According to the present invention, a silicon film can be easily formed on the substrate to a uniform thickness. The formed silicon film is made from amorphous silicon. This amorphous silicon film can be converted into a polycrystal silicon film by heating at a high temperature, for example, 700 to 900° C. under a nitrogen atmosphere, or exposure to laser light. Substrates made from various materials may be used as the substrate. For example, the substrate may be made from glass, ceramic, metal, synthetic resin or the like.

### EXAMPLES

The following examples are provided for the purpose of further illustrating the present invention but are in no way to be taken as limiting.

### Synthesis Example 1

(1) The inside of a 3-liter four-necked flask equipped with a thermometer, cooling condenser, dropping funnel and stirrer was substituted with argon gas, and 1 liter of dried tetrahydrofuran and 18.3 g of metallic lithium were charged into the flask and bubbled with argon gas. 333 g of diphenyldichlorosilane was added dropwise from the dropping funnel while this suspension was stirred at 0° C., and stirring was continued at room temperature for another 12 hours until metallic lithium completely disappeared after the end of addition. The reaction mixture was injected into 5 liters of iced water to precipitate the reaction product. This precipitate was separated by filtration, washed with water well and then with cyclohexane and vacuum dried to obtain 140 g of a white solid. It was confirmed from its IR, ¹H-NMR and ²⁹Si-NMR spectra that this white solid was a mixture of two components. When this silicon compound mixture was separated by high-speed liquid chromatography, it was found that the ratio of the main product to the by-product was 8:1. Further, when the IR, ¹H-NMR, 29Si-NMR and TOF-MS spectra of the main product and the by-product were measured, it could be confirmed that the main product was decaphenylcyclopentasilane and the by-product was dodecaphenylcyclohexasilane.

(2) 50 g of the above silicon compound mixture and 500 ml of dried toluene were charged into a 1-liter flask, 2 g of aluminum chloride was added, hydrogen chloride was introduced at room temperature and a reaction was continued under an argon atmosphere for 5 hours. Separately, 20 g of lithium aluminum hydride and 200 ml of diethyl ether were charged into a 2-liter flask, the above reaction mixture was added under agitation at 0° C. under an argon atmosphere and stirred at the same temperature for 1 hour, and stirring was further continued at room temperature for another 12 hours. After the aluminum compound was removed from the reaction mixture and the solvent was distilled off, 5 g of a viscous oily product was obtained. It was found from its IR, ¹H-NMR, ²⁹Si-NMR and GC-MS spectra that the product was a mixture containing cyclopentasilane and silylcyclopentasilane in a ratio of 8:1.

### Example 1

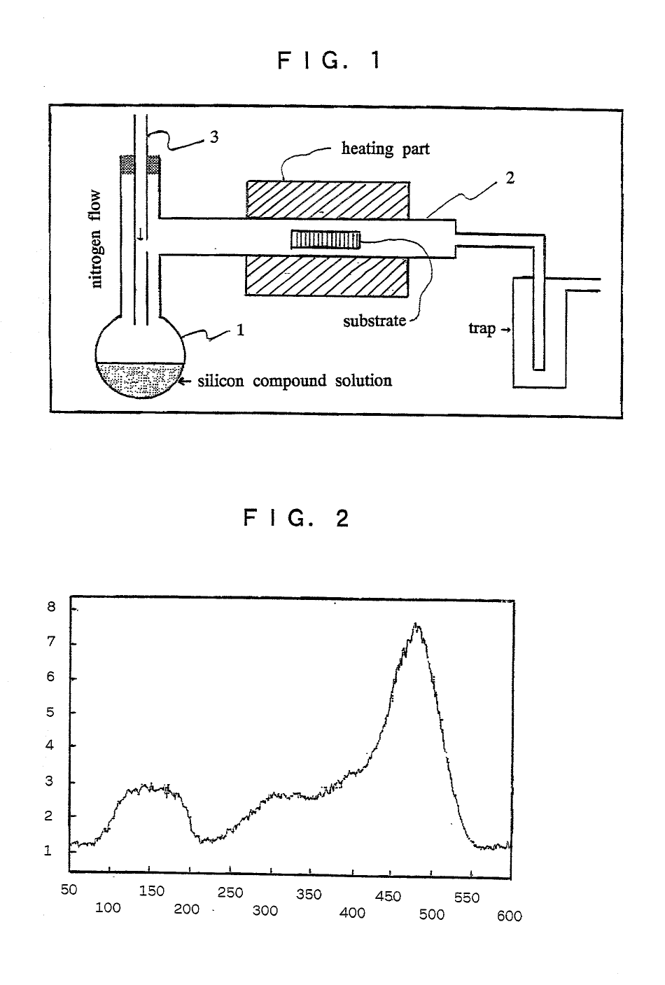

5 g of the silicon compound mixture obtained in Synthesis Example 1 was dissolved in 45 g of toluene under an argon atmosphere to prepare a solution. This solution was placed in a receiver 1 shown in FIG. 1 and a quartz glass substrate was set in a heating tube 2. When nitrogen gas was caused to flow from a gas introduction port 3 at a rate of 1 liter/min for 10 minutes while the heating tube 2 was heated at 400° C., a thin film having a metallic gloss was formed on the quartz substrate. The pressure of a toluene vapor at this point was 30 mmHg. When the ESCA spectrum of this thin film having a metallic gloss was measured, only a peak attributed to Si was observed at 99 eV and another element derived from the solvent such as carbon was not detected at all. The thickness of this silicon film was 80 nm. The Raman spectrum of this Si film is shown in FIG. 2. It was found from FIG. 2 that this film was made from amorphous silicon.

### Example 2

A silicon film having a metallic gloss could be formed on a quartz substrate in the same manner as in Example 1 except that the solvent for the silicon compound used in Example 1 was changed from 45 g of toluene to 45 g of xylene. When the Raman spectrum of this silicon film having a thickness of 44 nm was analyzed, it was found that this silicon film was an amorphous silicon film.

### Example 3

A silicon film could be formed on a polyimide substrate in the same manner as in Example 1 except that the polyimide film substrate was set in place of the quartz substrate used in Example 1 and the temperature of the substrate was changed to 300° C. This silicon film was amorphous as well.

### Comparative Example 1

A mixed gas of a monosilane compound and nitrogen gas was caused to flow into a device heated at 400° C. at a rate of 1 liter/min for 10 minutes in place of the silicon compound in the same manner as in Example 1. Nothing was accumulated on the quartz substrate.

As described above, according to the present invention, unlike CVD and plasma CVD, a silicon film can be formed on a substrate efficiently, for example, at a high yield and a high formation rate with simple operation or device.

What is claimed is:

1. A process for forming a silicon film on a substrate, comprising thermally decomposing at least one silicon compound selected from the group consisting of cyclopentasilane and silylcyclopentasilane in the presence of an inert organic medium vapor.

2. The process of claim 1, wherein the inert organic medium is at least one member selected from the group consisting of hydrocarbons and ethers.

3. The process of claim 1, wherein thermal decomposition is carried out at a temperature of 200 to 600° C.

4. A process for forming a silicon film on a substrate, comprising:
(1) introducing an inert gas into a mixture of at least one silicon compound selected from the group consisting of cyclopentasilane and silylcyclopentasilane and an inert organic medium to form a gas mixture containing the above silicon compound and inert organic medium vapor in the inert gas carrier; and
(2) heating the gas mixture to thermally decompose the silicon compound contained therein to deposit silicon on the substrate.

5. The process of claim 4, wherein the mixture of the silicon compound and the inert organic medium is in the form of a solution.

6. The process of claim 4, wherein the content of the silicon compound in the mixture of the silicon compound and the inert organic medium is 0.01 to 50 wt %.

7. The process of claim 4, wherein the inert organic medium is at least one member selected from the group consisting of hydrocarbons and ethers.

8. The process of claim 4, wherein thermal decomposition is carried out at a temperature of 200 to 600° C.
